(19) United States
(12) Patent Application Publication
(10) Pub. No.: US 2014/0291780 A1
(43) Pub. Date: Oct. 2, 2014

(54) MEMS DEVICE AND METHOD OF MANUFACTURING THE SAME

(71) Applicant: KABUSHIKI KAISHA TOSHIBA, Tokyo (JP)

(72) Inventor: Tomohiro SAITO, Yokohama-shi (JP)

(21) Appl. No.: 14/024,178

(22) Filed: Sep. 11, 2013

(30) Foreign Application Priority Data
Apr. 1, 2013 (JP) 2013-076091

(51) Int. Cl. B81B 3/00; B81C 1/00

(52) U.S. Cl. CPC B81B 3/0021; B81C 1/0038
USPC 257/415; 438/50

(57) ABSTRACT

According to one embodiment, a MEMS device including a first electrode provided on a support substrate, a second electrode opposed to the first electrode, having at least one end part overlapping the first electrode, and able to move in a direction it is opposed to the first electrode, and beam parts provided on the support substrate and supporting the second electrode. The surface of that part of the first electrode, which opposes the end part of the second electrode, is set at a lower level than the surface of that part of the second electrode, which opposes a center part of the second electrode.

### CROSS-REFERENCE TO RELATED APPLICATIONS

This application is based upon and claims the benefit of priority from Japanese Patent Application No. 2013-076091, filed Apr. 1, 2013, the entire contents of which are incorporated herein by reference.

### FIELD

Embodiments described herein relate generally to a MEMS device and a method of manufacturing the same.

### BACKGROUND

A micro-electromechanical system (MEMS) device, which comprises a movable electrode and a fixed electrode, has a low loss, high insulating property, and high linearity. It therefore attracts much attention, as a key device in the next-generation mobile telephones. Further, a MEMS capacitor has been proposed, which makes good use of the MEMS device and which can have a variable electrostatic capacitance.

However, any MEMS capacitor of this type fails to acquire desired capacitance. Further, a MEMS switch may not have sufficient reliability.

### BRIEF DESCRIPTION OF THE DRAWINGS

FIG. 1 is a plan view outlining the configuration of a MEMS device according to a first embodiment;

FIGS. 2A and 2B are sectional views taken along lines A-A′ and B-B′ shown in FIG. 1, respectively;

FIGS. 3A to 3D are sectional views showing the steps of manufacturing the MEMS device according to the first embodiment;

FIGS. 4A and 4B are plan views showing how the upper electrode and the lower electrode overlap;

FIG. 5 is a plan view showing how the upper electrode and the lower electrode overlap in another way;

FIG. 6 is a sectional view showing the major parts constituting a MEMS device according to a second embodiment;

FIG. 7 is a sectional views showing the major parts constituting a MEMS device according to a third embodiment;

FIG. 8 is a sectional views showing the major parts constituting a MEMS device according to the third embodiment;

FIG. 9 is a sectional views showing the major parts constituting a MEMS device according to a modified embodiment;

FIG. 10 is a sectional views showing the major parts constituting a MEMS device according to another modified embodiment; and

FIG. 11 is a sectional views showing the major parts constituting a MEMS device according to still another modified embodiment.

### DETAILED DESCRIPTION

In general, according to one embodiment, a MEMS device comprises a first electrode provided on a support substrate, a second electrode opposed to the first electrode, having at least one end part overlapping the first electrode, and able to move in a direction it is opposed to the first electrode, and beam parts provided on the support substrate and supporting the second electrode. A surface of that part of the first electrode, which opposes the end parts of the second electrode, is set at a lower level than the surface of that part of the second electrode, which opposes a center part of the second electrode.

MEMS devices according to embodiments will be described with reference to the accompanying drawings.

### First Embodiment

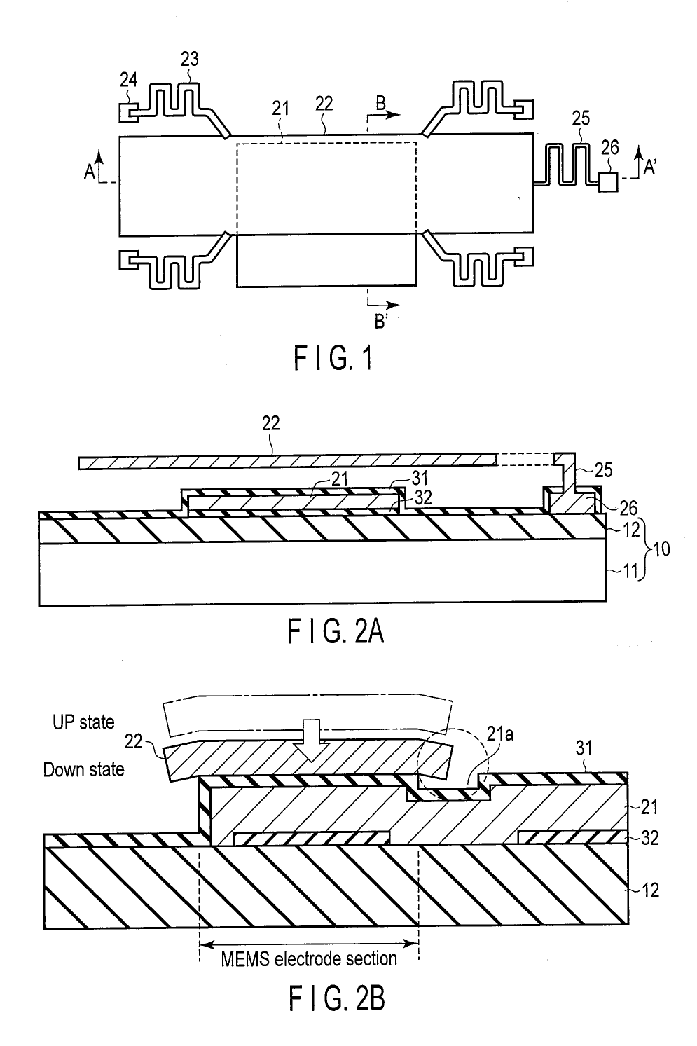

FIG. 1 is a plan view outlining the configuration of a MEMS device according to a first embodiment. FIG. 2A is a sectional view taken along line A-A′ shown in FIG. 1. FIG. 2B is a magnified sectional view taken along line B-B′ shown in FIG. 1. This embodiment is a device of the type that is driven with an electrostatic force as a voltage is applied between the upper and lower electrodes.

In FIGS. 2A and 2B, number 10 designates a support substrate composed of a Si substrate 11 and an insulating film 12, for example, silicon oxide film, formed on the Si substrate 11. The support substrate 10 may incorporate elements, such as field-effect transistors constituting a logic circuit or a memory circuit.

On the support substrate 10, a lower electrode (first electrode) 21 is provided and used as fixed electrode. The lower electrode 21 is, for example, rectangular, and is made of, for example, aluminum (Al) or Al alloy made mainly of aluminum. The material of the lower electrode 21 is not limited to these. Instead, the lower electrode 21 may be made of copper (Cu), platinum (Pt), tungsten (W), or the like.

Between the lower electrode 21 and the support substrate 10, a bump layer 32 is provide, which is made of silicon nitride film and patterned in accordance with the pattern of an upper electrode 22 (later described). That is, the bump layer 32 is formed below the entire upper electrode, but the end parts of thereof. Because of the bump layer 32, the lower electrode 21 has a recess 21a in the upper surface. The recess 21a is so deep that the end parts of the upper electrode 22 do not contact the lower electrode 21 before they contact the flat part of the lower electrode 21 when the MEMS device is driven to make the upper electrode 22 contact the lower electrode 21.

A capacitor insulating film 31 made of, for example, silicon nitride film, and having thickness of 100 nm is formed, covering the surface of the lower electrode 21. The capacitor insulating film 31 may be a high-k film instead, which has a larger dielectric constant than SiOx and SiN.

An upper electrode (second electrode) 22, or a movable electrode, is arranged above the lower electrode 21 and opposed to the lower electrode 21. The upper electrode 22 is rectangular and larger than the lower electrode 21, overlapping the lower electrode 21. The upper electrode 22 is made of, for example, material such as Al, Al alloy, Cu, Au or Pt. The material of the upper electrode 22 is not limited to ductile material, nevertheless. The upper electrode 22 may be made of brittle material such as tungsten (W).

As shown in FIG. 2B, the end parts of the upper electrode 22 bends downward because of the process, which will be described later. The end parts of the upper electrode 22 so bending are aligned with the recess 21a.

As shown in FIG. 1, the lower electrode 21 and the upper electrode 22 are rectangular as seen from above. They may be shaped like a square, a circle or an ellipse, instead.

The upper electrode 22 is connected, at some parts, to anchor parts 24 provided on the support substrate 10, by first spring parts (beam parts) 23. The first spring parts 23 and the anchor parts 24 are provided at several positions (for example, four positions). The first spring parts 23 are, for example, silicon nitride films, have meandering shape, and has elasticity. These spring parts 23 enable the upper electrode 22 to move up and down.

The upper electrode 22 is connected, at one part, to an anchor part 26 provided on the substrate 10, by a second spring part 25 made of electrically conductive material. The second spring part 25 may be made integral with the upper electrode 22 and may extend therefrom. The second spring part 25 achieves electrical conduction with the upper electrode 22, and is very slender and made of elastic material such as Al.

A dome layer (not shown) may be provided, covering the space in which the upper electrode 22, spring parts 23 and 25 can move.

In this embodiment, the lower electrode 21 has a recess 21a in its surface and below an end part of the upper electrode 22. Therefore, even if the upper electrode 22 bends at the end parts, this end part will not contact the lower electrode 21 before any other part of the upper electrode 22 contact the lower electrode 21.

An MEMS capacitor may not acquire desired capacitance, failing to exhibit good characteristics. The reason why can be inferred as follows.

In the MEMS capacitor, the upper electrode (movable electrode) may fail to have a flat surface in some cases. The end parts of the upper electrode bending downward during, for example, a process of forming a sacrificial layer to provide a space around the upper electrode, curing the sacrificial layer and removing the sacrificial layer. Once the edge parts of the upper electrode have bent, they contact the lower electrode before any other part. As a result, an air layer is formed between the flat part of the upper later and the lower electrode.

In this case, the capacitor, which is composed of the upper electrode, lower electrode and the insulating film formed on the lower electrode cannot acquire sufficient capacitance. To achieve a sufficiently firm contact of the upper and lower electrodes, the voltage applied between the electrodes must be raised. That is, to saturate the capacitance fully, a high voltage should be applied between the electrodes.

In the case of an MEMS switch, the edge parts of the upper electrode contact the lower electrode before any other part. The electric field inevitably concentrates at the edge parts of both electrodes. This will reduce the reliability of the MEMS switch.

In the MEMS device according to this embodiment, a recess 21 is made in the surface of the lower electrode 21, and the end parts of the upper electrode 22 will not contact the lower electrode 21 even if they bend before any other part. Even if the end parts of the upper electrode 22 bend downward, they are prevented from contacting the lower electrode 21 before any other part contacts the lower electrode 21.

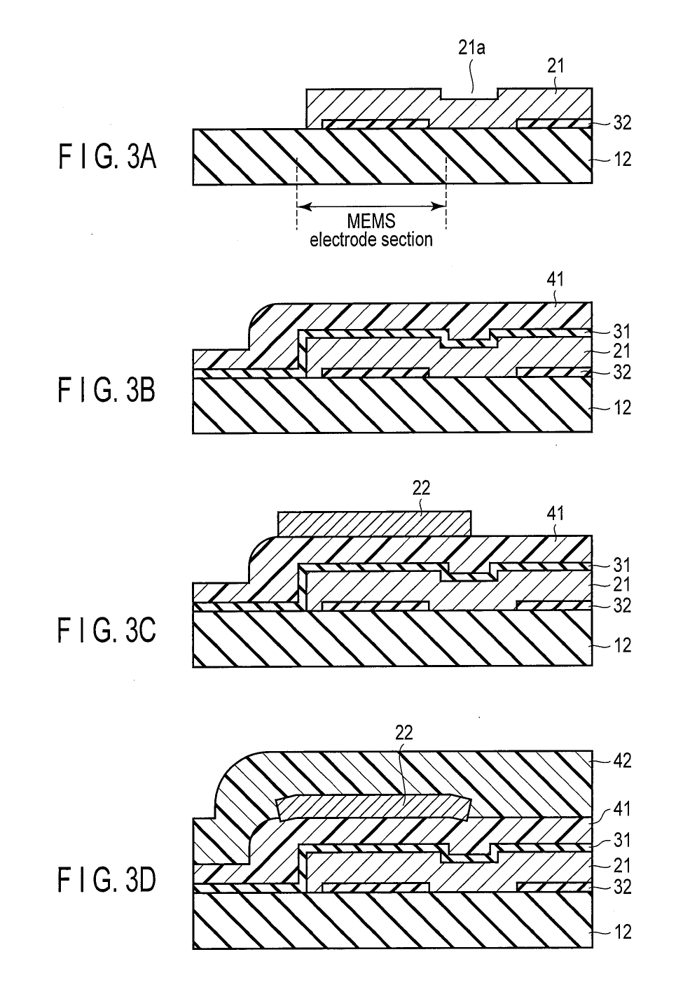

A method of manufacturing the MEMS device according to this embodiment will be explained with reference to FIGS. 3A to 3D. FIGS. 3A to 3D are equivalent to the sectional views taken along line B-B′ shown in FIG. 1.

First, as shown in FIG. 3A, a bump layer 32 is formed on a support substrate 10 composed of a substrate 11 made of, for example, Si and an insulating film 12 formed on the substrate 11. More precisely, a silicon nitride film is formed on the entire surface of the insulating film 12, i.e., lower layer, and is then processed by, for example, resist patterning and dry etching. At this point, the silicon nitride film has thickness almost equivalent to the step which will be formed on the upper surface of the lower electrode 21.

More specifically, the end parts of the upper electrode 22 only needs to have a height large enough not to contact the lower electrode 21 when it bends after a sacrificial layer (later described) is removed, and large enough not to degrade the flatness of a sacrificial layer which will be formed thereafter. The height of the silicon nitride film is, for example, about 100 to 400 nm. This value is no more than an example, because the height of the end parts depends on the thickness of the sacrificial layer and the thickness of the upper electrode.

The pattern of the bump layer 32, which define the projecting parts of the lower electrode 21, will be formed on the entire upper electrode 22, but the edge parts, or will be formed on some parts of the upper electrode 22. Nonetheless, the lower electrode 21 is formed isotropic if it has thickness of about 1 μm, though its thickness depends on the method of forming it. In this case, the recesses and projections defined by the bump layer 32 are displaced with respect to those of the lower electrode 21 by the thickness of the lower electrode 21. The thickness of the lower electrode 21 should therefore be taken into consideration as conversion difference when the silicon nitride film is patterned. Since the recess made in the lower electrode 21 defines the width of the bend parts of the upper electrode 22, it may extend, in some case, for several microns from the ends of the upper electrode 22.

The pump layer 32 may be made of electrically conductive material, not made of insulating film. The bump layer 32 may be formed by patterning a photosensitive layer. Alternatively, the bump layer 32 may be formed on the support substrate 10 by the selective CVD method. For example, silicon (Si) may be formed selectively on the support substrate 10 and CVD is then performed, using WF6. In this case, W film grows while Si is acting as catalyst, and can be used as bump layer 32.

Next, a layer of electrode material (for example, Al alloy) is formed on the entire surface to form the lower electrode and wires connected to the lower electrode. This layer is then patterned, forming the lower electrode 21. The layer can be patterned by, for example, pattern transfer using resist and anisotropic etching of a layer of electrode material. At this point, recesses and projections are formed at the upper surface of the lower electrode 21, in conformity with the pattern of the bump layer 32 formed under the lower electrode 21. That is, the recess 21a is made in that part of the lower electrode 21, which will lie below an end part of the upper electrode 22. The anchor parts 24 and the anchor part 26, all mentioned above, can be formed at the same as the lower electrode 21.

Then, as shown in FIG. 3B, an insulating film (for example, silicon nitride film) 31, which will be capacitor insulator, is formed, covering the exposed surface of the lower electrode 21. Thereafter, a sacrificial layer 41 made of organic material such as polyimide is formed by coating on the entire surface of the structure, in order to provide a space between the lower electrode 21 and the upper electrode 22 (for signal line and drive line). At this point, the recess and projection (defining a step) at the upper surface of the lower electrode 21 are not so prominent. Further, the organic material has fluidity. Hence, the sacrificial layer 41 has an almost flat upper surface.

Then, the sacrificial layer 41 is patterned to form anchor parts (not shown) for positioning the upper electrode. The sacrificial layer 41 is patterned by, for example, transfer using resist and etching. The sacrificial layer 41 is cured, as needed.

Further, as shown in FIG. 3C, upper electrode material is applied, forming a layer. The layer is patterned, forming an upper electrode 22, a drive electrode and a bias line (not shown), second spring parts 25, etc. At this point, that part of the lower surface of the upper electrode 22, which opposes the lower electrode 21, is almost flat.

Next, first spring parts 23 (not shown) are formed, which supports the upper electrode 22. For example, a silicon nitride film is formed on the sacrificial layer 41, covering the upper electrode 22 and the anchor parts 24. Thereafter, the silicon nitride film is patterned, leaving the part extending from the upper electrode 22 to the anchor parts 24. The first spring parts 23 can be formed at the same time as the upper electrode 22.

Then, as shown in FIG. 3D, a second sacrificial layer 42 is formed to provide a space between the upper electrode and a thin-film dome. The second sacrificial layer 42 is formed and patterned in the same way as the first sacrificial layer 41, and is then cured. At this point, the second sacrificial layer 42 shrinks, exerting a force. The force bends the end parts of the upper electrode 22 downwards. The degree of this bending (degree of deformation) depends on the thickness, shrink rate and curing condition of the second sacrificial layer 42 and the thickness, rigidity and pattern of the upper electrode 22.

Thereafter, a film is deposited for forming a dome and patterned in order to remove the first sacrificial layer 41 and second sacrificial layer 42. The sacrificial layers 41 and 42 are then removed, providing a structure in which the upper electrode 22 is supported in midair.

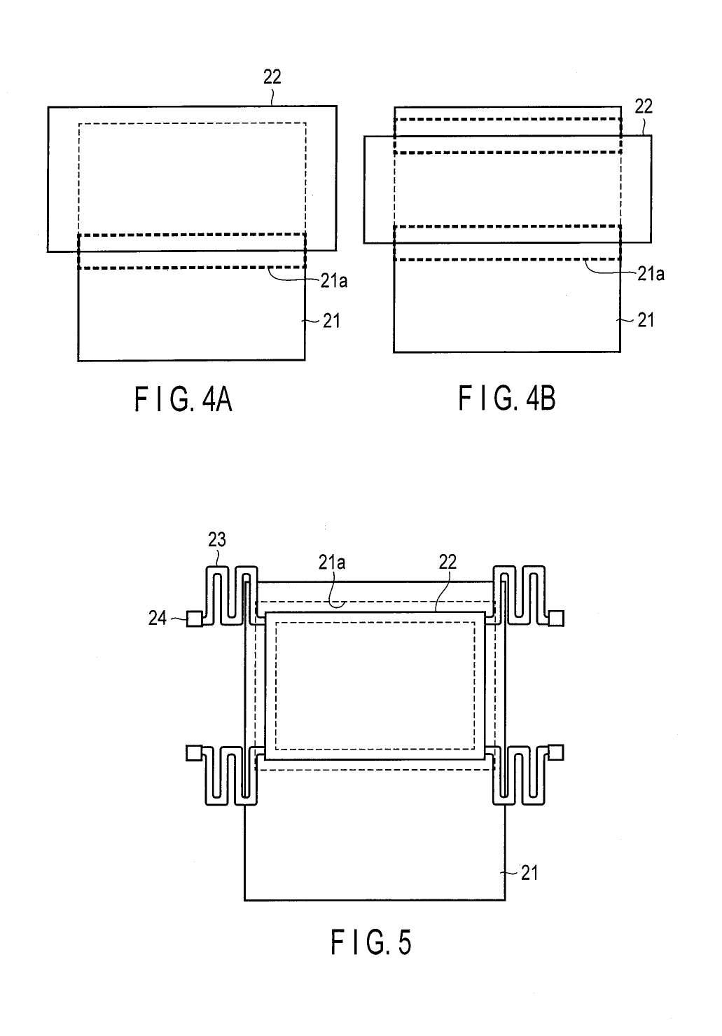

The upper electrode 22 may overlap the lower electrode 21 in various manners. FIG. 4A shows the upper electrode 22 with one end part overlapping the lower electrode 21 as illustrated in FIG. 1. In this case, a recess 21a (indicated by thick broken lines) may be made in that part of the lower electrode 21, which lies below one end part of the upper electrode 22.

FIG. 4B shows the upper electrode 22 with two opposing end parts overlapping the lower electrode 21. In this case, two recesses 21a may be made in those parts of the lower electrode 21, which lie below the opposing end parts of the upper electrode 22, respectively.

FIG. 5 shows the case where all four sides of the upper electrode 22 overlap the lower electrode 21. In this case, recesses 21a are made in all sides of the lower electrode 21.

In this embodiment, the bump layer 32 is formed on the support substrate 10, conforming to the pattern of the upper electrode 22. The recesses 21a are thereby made in the lower electrode 21, at the positions where the end parts of the upper electrode 22 lie above the lower electrode 21. Therefore, even if the end parts of the upper electrode 22, which constitutes a capacitor jointly with the lower electrode 21, bend toward the lower electrode 21, the end parts of the upper electrode 22 are prevented from contacting the lower electrode 21 before any other part contacts the lower electrode 21. This prevents an air layer from being formed between the upper electrode 22 and the lower electrode 21, and the electrostatic capacitance will never decrease below the design value. Thus, a variable capacitor according to this embodiment excels in capacitance characteristic.

The capacitance does not vary as the voltage applied changes. This helps to enhance the yield of the product. In addition, if the embodiment is applied to a switch, the switch will acquire high reliability because the electric field would not concentrate at the edge parts of the electrodes.

### Second Embodiment

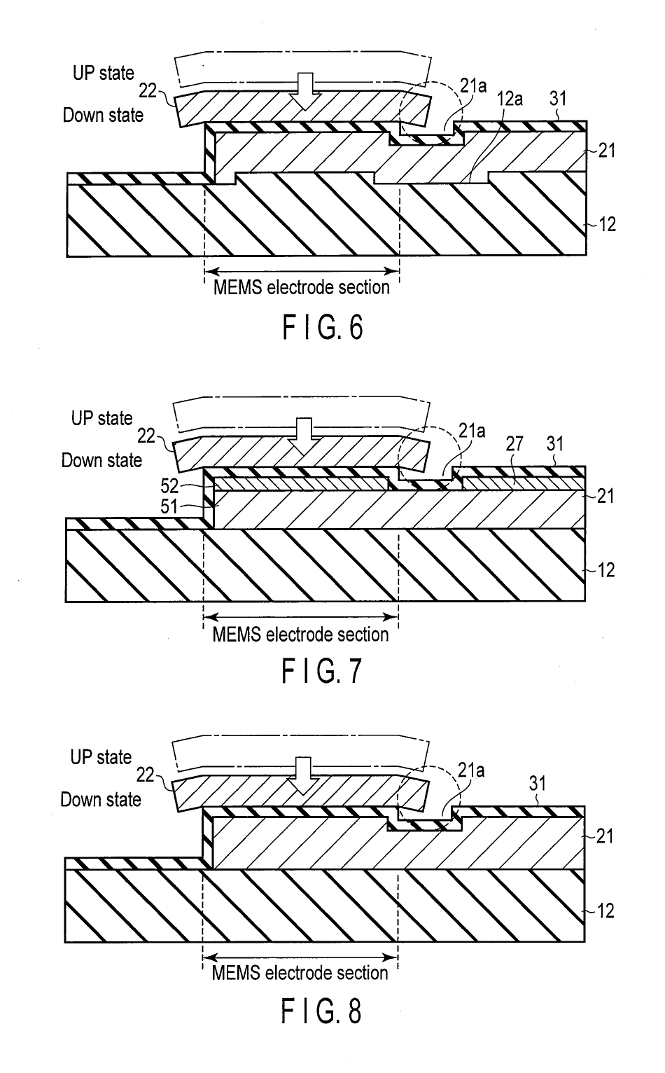

FIG. 6 is a sectional view showing the major parts constituting a MEMS device according to a second embodiment. The components identical to those shown in FIG. 1, FIG. 2A and FIG. 2B are designated by the same reference numbers and will not be described in detail. This embodiment differs from the first embodiment described above, in that recesses and projections are made at the surface of the support substrate, instead of forming a bump layer. That is, recesses 12a are made in the surface of the insulating film 12 of the support substrate 10, in alignment with the end parts of the upper electrode 22.

More specifically, a bump structure is formed on the insulating film 12 of the support substrate 10, in order to form steps at the upper surface of the lower electrode 21. First, the surface of the insulating film 12 is resist-patterned and etched. The etching may be, for example, dry etching or wet etching. Then, the resist is removed, and the lower electrode 21 is formed, which has recesses and projections at the upper surface. The steps made at the upper surface of the insulating film 12 have a depth and pattern similar to those of the bump layer 32 formed in the first embodiment. Thereafter, manufacturing steps will be performed, which are identical to those performed in the first embodiment.

Thus, in this embodiment, the recesses 12a are made in the surface of the insulating film 12 of the support substrate 10. As a result, recesses 21a are made in the surface of the lower electrode 21, in alignment with the recesses 12a. Therefore, the end parts of the upper electrode 22 will not contact the lower electrode 21 even if the upper electrode 22 constituting the capacitor or the like are bend toward the lower electrode 21. This embodiment can therefore achieve the same advantage as the first embodiment.

### Third Embodiment

FIG. 7 and FIG. 8 are sectional views showing the major parts constituting a MEMS device according to a third embodiment. The components identical to those shown in FIG. 1, FIG. 2A and FIG. 2B are designated by the same reference numbers and will not be described in detail.

This embodiment differs from the first embodiment, in that recesses and projections are made at the surface of the lower electrode 21 by means of, for example, etching, without forming a bump layer.

To be more specific, the lower electrode 21 is formed on the support substrate 10. Then, recesses and projections are made at the upper surface of the lower electrode 21. For example, the lower electrode 21 composed of a lower film 51 and an upper film 52 is first formed, and the upper film 52 is then patterned and etched, thereby making the recesses and projections. More precisely, an upper film 52 as thin as the depth of the recesses 21a is formed on the lower film 51 which is relatively thick, and the upper film 52 is then etched by means of, for example, RIE, at some positions, thus making the recesses and projections.

Another method is to perform resist patterning on the lower electrode 21 as shown in FIG. 8, and etching is then performed, making recesses and projections at the upper surface of the lower electrode 21. It does not matter whether the recesses and projections are formed before or after the patterning of the lower electrode. Moreover, a cover film may be formed, for example after the etching. Thereafter, manufacturing steps will be performed, which are identical to those performed in the first embodiment.

In this embodiment, recesses and projections are made at the surface of the lower electrode 21, and the recesses 21a made in the surface of the lower electrode 21 are aligned with the end parts of the upper electrode 22. This prevents the end parts of the upper electrode 22 from contacting the lower electrode 21.

Hence, the second embodiment can achieve the same advantage as the first embodiment.

### Modified Embodiments

This invention is not limited to the embodiments described above.

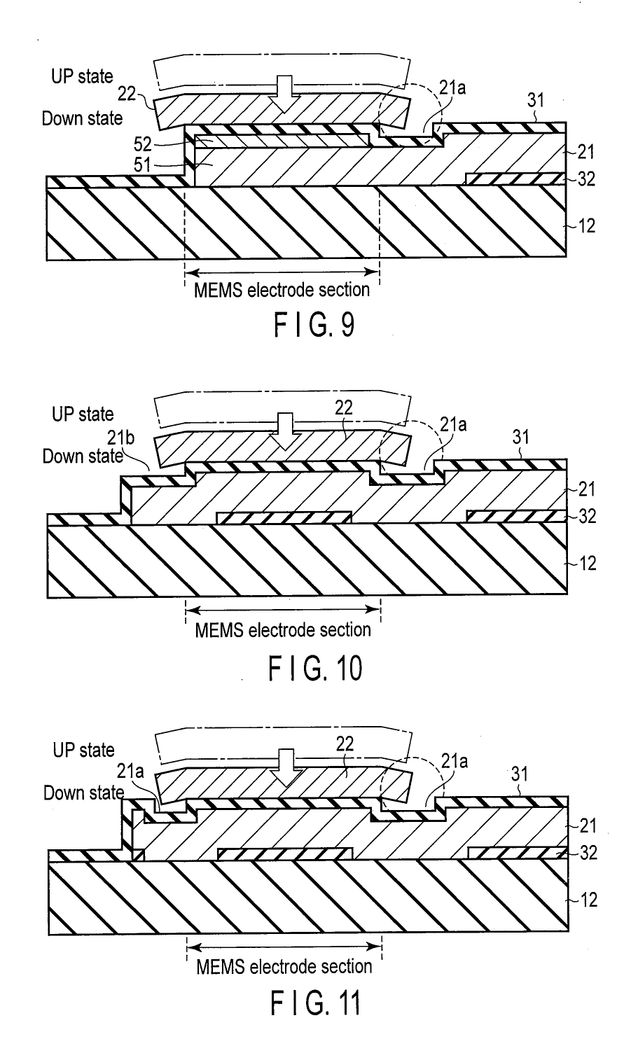

As shown in FIG. 9, second and third embodiments may be combined, thereby forming a bump layer 32 and the lower electrode 21 may be processed at surface. Further, if both end parts of the upper electrode 22 overlap the lower electrode 21 as shown in FIG. 10 and FIG. 11, recesses 21a may be made in the lower electrode 21, in alignment with both end parts of the upper electrode 22. As shown in FIG. 10, the lower electrode 21 extends, at left end, only a little with respect to the upper electrode 22. Therefore, not a recess 21a, but a step 21b is formed at the left end lower electrode 21. Thus, a step at a lower level than the center part of the lower electrode 21 may be formed, instead of a recess, at any end part of the lower electrode 21, which opposes the end part of the lower electrode 21. As shown in FIG. 11, recesses 21a are made in both end parts of the lower electrode 21, which oppose the end parts of the upper electrode 22. The recess 21a is more effective than the step 21b to flatten the sacrificial layer before the upper electrode 22 is formed.

The support substrate is not limited one composed of a Si substrate and a silicon oxide film formed on the Si substrate. An insulating substrate made of, for example, glass can be used instead. Further, the beam parts provided for the upper electrode need not be made of material different from the material of the upper electrode. Rather, they may be made of the same material as the upper electrode, and may be formed at the same time as the upper electrode.

Any embodiment described above is a device driven with an electrostatic force generated by applying a voltage between the upper and lower electrodes. Nonetheless, this invention can be applied to a MEMS structure which has electrodes made of different metals and laid one on the other, and which is driven by the piezoelectric force generated by the laminate composed of these electrodes.

Any embodiment described above is a MEMS capacitor. This invention can be applied to a MEMS switch, nevertheless. In this case, a part of the capacitor insulating film formed on the lower electrode, for example that part contacting the upper electrode, is removed by means of patterning and etching, thereby exposing the surface of the lower electrode. As a result, the upper electrode and the lower electrode constitute a switch. As the electrodes are driven by upper and lower drive electrodes, respectively, the structure operates as a switch.

Any embodiment described above has two electrodes, i.e., lower electrode and upper electrode. Nonetheless, this invention can be applied to a MEMS device having three or more electrodes (for example, fixed upper electrode, fixed lower electrode and movable intermediate electrode). Moreover, each electrode can be set to any size, in accordance with the electrostatic capacitance required.

Furthermore, even in a configuration having no bump layers beneath the lower electrode, the selective CVD method may be used, in which the speed of forming the lower electrode is changed, thereby to change the film thickness. For example, a Si film may be selectively formed or exposed on the surface of the support substrate, and CVD may then be performed, using WF6 as material gas, thereby to make W grow by using Si as catalyst.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a first electrode provided on a support substrate;
a second electrode opposed to the first electrode, having at least one end part overlapping the first electrode, and able to move in a direction it is opposed to the first electrode; and
beam parts provided on the support substrate and supporting the second electrode,
wherein a surface of that part of the first electrode, which opposes the end part of the second electrode is set at a lower level than the surface of that part of the second electrode, which opposes a center part of the second electrode.

2. The device according to claim 1, wherein a recess is made in the first electrode, in a region where the end part of the second electrode overlaps the first electrode.

3. The device according to claim 2, wherein the recess of the first electrode has been made by etching the surface of the first electrode.

4. The device according to claim 1, further comprising a bump layer formed between the support substrate and the first electrode, in order to provide a step on the surface of the first electrode.

5. The device according to claim 1, wherein a step is formed on the surface of the support substrate, in order to provide a step on the surface of the first electrode.

6. The device according to claim 1, wherein the first electrode is composed of a lower layer formed on the support electrode and an upper layer laid on the lower layer, and the upper layer is formed outside a region in which the end part of the second electrode overlaps the first electrode.

7. The device according to claim 1, wherein the end part of the second electrode bends downward.

8. The device according to claim 1, wherein both end parts of the upper electrode overlap the lower electrode.

9. The device according to claim 1, wherein four sides of the upper electrode all overlap the lower electrode.

10. The device according to claim 1, wherein the end part of the second electrode bends downward, and a recess is made in the first electrode, in a region where the end part of the second electrode overlaps the first electrode.

11. The device according to claim 10, wherein the recess of the first electrode has been made by etching the surface of the first electrode.

12. The device according to claim 10, further comprising a bump layer formed between the support substrate and the first electrode, in order to provide a step on the surface of the first electrode.

13. The device according to claim 10, wherein a step is formed on the surface of the support substrate, in order to provide a step on the surface of the first electrode.

14. The device according to claim 10, wherein the first electrode is composed of a lower layer formed on the support electrode and an upper layer laid on the lower layer, and the upper layer is formed outside a region in which the end part of the second electrode overlaps the first electrode.

15. The device according to claim 10, wherein both end parts of the upper electrode overlap the lower electrode.

16. The device according to claim 10, wherein four sides of the upper electrode all overlap the lower electrode.

17. A method of manufacturing a MEMS device, comprising:
forming, on a support substrate, a first electrode having a recess in a part of a surface;
forming a sacrificial layer covering the first electrode;
forming, on the sacrificial layer, a second electrode having a region which overlaps the recess made in the first electrode and in which at least one end part the second electrode is aligned with the recess made in the first electrode; and
removing the sacrificial layer after the second electrode has been formed.
